(19) United States
(12) Patent Application Publication
(10) Pub. No.: US 2026/0223733 A1
(43) Pub. Date: Jul. 30, 2026

(54) IMAGE SENSOR WITH IN-PACKAGE NOISE-DECOUPLING

(71) Applicant: SEMICONDUCTOR COMPONENTS INDUSTRIES, LLC, Scottsdale, AZ (US)

(72) Inventors: Nicholas Paul COWLEY, Wroughton (GB); Andrew David TALBOT, Chieveley (GB)

(73) Assignee: SEMICONDUCTOR COMPONENTS INDUSTRIES, LLC, Scottsdale, AZ (US)

(21) Appl. No.: 19/037,552

(22) Filed: Jan. 27, 2025

(51) Int. Cl. H01L 25/16; H01L 23/00; H01L 25/00; H10D 1/68; H10F 39/00; H10F 39/95

(52) U.S. Cl. CPC H10W 90/00; H10D 1/68; H10F 39/024; H10F 39/806; H10F 39/811; H10F 39/95; H10W 90/754

(57) ABSTRACT

An image sensor includes a noise-decoupling device, such as a capacitor, directly connected to a top surface of a sensor-die, in order to reduce artifacts in an image caused by noise. The noise, which may be from switching circuitry within the image sensor, can be reduced more efficiently when the capacitor is directly coupled directly to the image-sensor die because the decoupling path to ground may experience less resistance than longer decoupling paths.

### FIELD OF THE DISCLOSURE

The present disclosure relates to image sensors and more specifically to a noise reduction technique for image sensors.

### BACKGROUND

Image sensors (e.g., complementary metal oxide semiconductor (CMOS) image sensors) include photosensitive pixels, arranged in rows and columns, configured to generate signals (e.g., voltages) in proportion to the light at each pixel. The rows and columns of the array of pixels may be addressed in sequence to obtain the signals for the pixels. There are many sources of noise in an image sensor. The noise may create temporal and/or spatial variations, which can create visible artifacts in the images that are ultimately rendered. Noise reduction techniques exist to reduce spatial noise, but temporal noise (i.e., signal noise) may be much more difficult to reduce and can limit the performance of the image sensor.

### SUMMARY

An image sensor is disclosed that can reduce signal noise using a noise-decoupling device directly coupled to a sensor-die of an image sensor. The location can improve the reduction of the noise compared to other decoupling techniques in which the noise-decoupling device is indirectly coupled to the die of the image sensor.

In some aspects, the techniques described herein relate to an image sensor, including: a sensor-die including: an active pixel region including active pixels; and a reference pixel region including reference pixels; a metal layer deposited on a top surface of the sensor-die, the metal layer including: a shield aligned with the reference pixel region and configured to block light received at the top surface of the metal layer from reaching the reference pixels in the reference pixel region and to pass the light received at the top surface of the metal layer to the active pixels in the active pixel region; and a pad including an interconnect portion and a decoupling portion; and a noise-decoupling device coupled to the decoupling portion of the pad.

In some aspects, the techniques described herein relate to a method for reducing noise in an image sensor, the method including: depositing a shield on a top surface of a sensor-die to block light from reaching reference pixels in a reference pixel region of the sensor-die and to pass the light to active pixels in an active pixel region of the sensor-die; depositing a pad including an interconnect portion and a decoupling portion on the top surface of the sensor-die; receiving a power signal at the interconnect portion of the pad; routing the power signal to circuitry using a through-silicon via coupled to the interconnect portion of the pad; receiving a noise signal at the pad; and coupling the noise signal at the pad, and not coupling the power signal at the pad, to a ground using a noise decoupling device disposed on the top surface of the sensor-die.

In some aspects, the techniques described herein relate to an image sensor including: a printed circuit board including a power supply configured to generate a power signal; a package coupled to the printed circuit board, the package including a lead frame configured to receive the power signal; a sensor-die coupled to the lead frame to receive the power signal, the sensor-die including: a shield deposited on a top surface of the sensor-die configured to block light from reaching reference pixels in a reference pixel region of the sensor-die and to pass the light to active pixels in an active pixel region of the sensor-die; and a pad deposited on the top surface of the sensor-die, an integrated circuit including switching circuitry that generates a noise signal (in addition to other signals), the noise signal coupled to the pad by a through-silicon via; and a noise-decoupling device coupled between the pad and a ground on the top surface of the sensor-die, the noise-decoupling device configured to conduct the noise signal at the pad to the ground and not conduct the power signal at the pad to the ground.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1 is a top view of a sensor-die for an image sensor according to a possible implementation of the present disclosure.

FIG. 2 is a side cross-sectional view of a portion of a camera module according to a possible implementation of the present disclosure.

FIG. 3A is a top view of a portion of an image sensor according to a first possible implementation of the present disclosure.

FIG. 3B is a top view of a portion of an image sensor according to a second possible implementation of the present disclosure.

FIG. 3C is a top view of a portion of an image sensor according to a third possible implementation of the present disclosure.

FIG. 3D is a top view of a portion of an image sensor according to a fourth possible implementation of the present disclosure.

FIG. 4 is a top view of a pad of an image sensor according to a possible implementation of the present disclosure.

FIG. 5 is a flowchart of a method for reducing noise in an image sensor according to a possible implementation of the present disclosure.

The components in the drawings are not necessarily to scale relative to each other. Like reference numerals designate corresponding parts throughout the several views.

### DETAILED DESCRIPTION

Noise-decoupling devices may be added to circuits to separate noise signals from other signals. After separating (i.e., decoupling), the noise signals may be routed to ground along a decoupling path to remove their influence on the circuit. Noise decoupling over a long decoupling path may be less effective because of parasitic impedances, which can couple the noise signals to other circuitry and/or lead to unwanted resonances. Accordingly, it may be advantageous to position the noise-decoupling device close to the source of the noise signals and the ground of the system to minimize the parasitic impedances and their effects.

Image sensors are especially sensitive to noise signals, which can generate artifacts in images rendered from the pixel signals. One technical problem facing image sensors, however, is that the noise is higher than desired because packaging requirements create a relatively long decoupling path. The present disclosure describes a camera module including an image sensor with a noise-decoupling device directly connected to a sensor-die in order to reduce the length of a noise decoupling path to reduce the signal noise.

Image sensors (e.g., CMOS image sensors) include circuitry for spatially sensing light (i.e., sensing circuitry). The sensing circuitry may include pixels (e.g., photodiodes), which are arranged in a two-dimensional array and coupled to row conductors and column conductors by transistors. Image sensors further include circuitry for processing (i.e., processing circuitry). The processing circuitry may include switching circuitry to select (i.e., activate) pixels for readout and to reset pixels after they have been read. The processing circuitry may also be configured to perform analog-to-digital conversion, which may also require switching circuitry.

The sensing circuitry and the processing circuitry can be combined in the same substrate. Image sensors in this configuration are known as monolithic. Alternatively, the sensing circuitry and the processing circuitry can be in separate substrates that are bonded together at interconnection layers (i.e., metal stacks). Image sensors in this configuration are known as stacked because they include a stack of substrates and layers that function as the image sensor (i.e. image-sensor stack). The disclosed techniques may be applied to monolithic or stacked configurations.

An image sensor (e.g., CMOS image sensor) may include a layer of semiconductor (i.e., silicon) material in which photodiodes are fabricated. This layer may be referred to as the sensor-die because it may be the product of a wafer that is diced to separate each sensor. The sensor-die may include layers of conductive traces (i.e., sensor metal stack) for routing signals and power to/from the photodiodes. The image sensor may be configured so that (incident) light is received through the sensor metal stack before reaching the photodiodes of the sensor-die, which can be on the same side of the sensor die as the conductive traces. Image sensors in this configuration are known as front side illuminated (FSI) image sensors. Alternatively, the image sensor may be configured so that the light is received at the photodiodes with the conductive traces disposed on the opposite side to the photodiodes. Image sensors in this configuration are known as backside illuminated (BSI) image sensors. The disclosed techniques may be applied to FSI image sensors or BSI image sensors. In what follows, the implementation of a BSI image sensor in a stacked configuration will be described in detail and will be referred to simply as the image sensor. The term “top” is used herein to imply the surface of the image-sensor stack facing the light received by the sensor. For example, the top surface of a BSI image sensor may correspond to the back surface of a sensor-die.

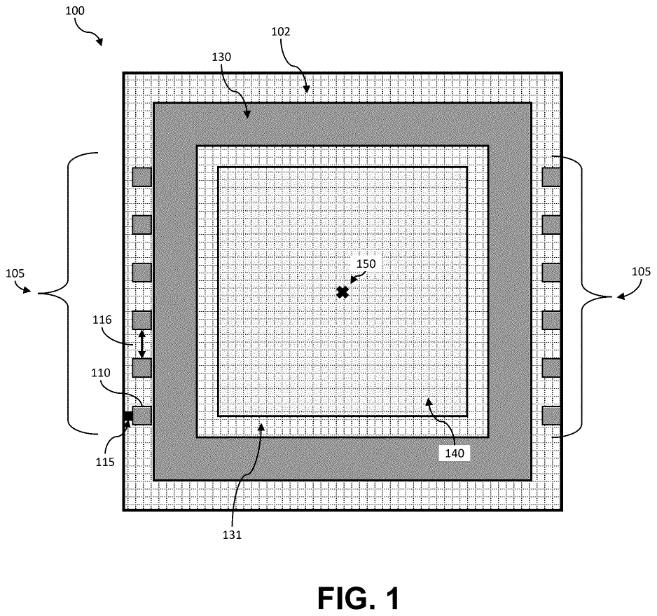

FIG. 1 is a top view of a sensor-die 100 according to a possible implementation of the present disclosure. In other words, FIG. 1 shows a top surface of the sensor-die 100. A metal layer is deposited on the top surface of the sensor-die 100 and is etched, or otherwise removed, to define a shield 130 and one or more pads (e.g., a plurality of pads 105). In other words, the metal layer deposited on the top surface of the sensor-die 100 includes a shield 130 and at least one pad.

As shown in FIG. 1, the shield 130 may be a square annulus that includes an outer square edge and a concentric inner square edge, which, in a possible implementation, are aligned to a center 150 of the sensor-die 100. In FIG. 1, items may be referred to as inner (i.e., inside) or outer (i.e., outside) based on their proximity to the center 150, with inner items being closer to the center 150 than outer items. FIG. 1 is shown to illustrate features on the top surface of the sensor-die and is not intended to limit the present disclosure to this particular arrangement. For example, in a possible implementation, the die can be rectangular (landscape format) so that the anulus will be wider in a horizontal direction than in a vertical direction. In another possible implementation, if the array center is offset to die center in the horizontal direction, then the annulus will have a different width on left and right side (i.e., will be non-symmetric).

One or more pads (e.g., a plurality of pads 105) may be deposited on a top surface of the sensor-die 100 so that the pad, or pads, are located in a pad region 102 of the sensor-die 100, which is between the outer edge of the shield 130 and the edge of the sensor-die 100. A pad 110 may be configured to electrically couple circuitry associated with the sensor-die 100 to an interconnect (e.g., lead frame) of the semiconductor package (i.e., package) containing the sensor-die 100. Accordingly, the pad 110 may be connected to a through-silicon-via (TSV 115) and to a wire from a lead frame (not shown). In a possible implementation, the connection, which couples the wire to the pad 110, is a wire-bond (e.g., wedge wire-bond).

The pad region 102 may include pads spaced according to a pad pitch 116. The pad pitch may be selected to provide clearance for a wire-bonding process. As shown, each pad 110 of the plurality of pads 105 may be square with an outer edge that is approximately flush with a side of the sensor-die 100. In practice, each pad may be inset from the edge of the die by a small distance (e.g., 10-100 microns) to reduce chance of mechanical damage. As shown, pads of the plurality of pads 105 may be located at more than one side of the sensor-die 100. In a possible implementation, a pad 110 is coupled to an upper rail (i.e., power supply) of the image sensor to receive a power signal (V_{DD}) and the shield 130 is coupled to a lower rail (i.e., ground) to conduct noise to a ground voltage (V_{SS}) of the image sensor, where the noise can include electrical noise as well as light induced charge that can build up in the sensor. In another possible implementation, a first pad is coupled to the upper rail (i.e., power supply, V_{DD}) of the image sensor and a second pad is coupled to the lower rail (i.e., ground, V_{SS}) of the image sensor.

The sensor-die 100 includes a plurality of pixels. Accordingly, the top surface of the sensor-die 100 and the top surface of the image sensor may be referred to interchangeably as the top surface. The shield 130 can be an optically opaque material, such as a metal (e.g., copper). The shield 130 can block light received at the top surface of the sensor-die 100 from reaching a region of the sensor-die 100 that is behind (i.e., under) the shield.

The region behind (i.e., under) the shield may include reference pixels (i.e., black pixels) that are shielded from light, and therefore, this region may be referred to as the reference pixel region. In other words, the region defined by the shield 130 in FIG. 1 may define (e.g., spatially match) the reference pixel region. A region of the sensor-die 100 that is within the inner edge of the shield 130 (i.e., within an aperture of the shield 130) may include active pixels configured to sense (i.e., measure) incident light, and therefore, this region may be referred to as the active pixel region 140.

The reference pixels (i.e., black pixels) in the reference pixel region can include photodiodes that match photodiodes of the active pixels in the active pixel region 140. Signals from the reference pixels can be used to reduce noise in the pixel levels generated by the image sensor. For example, a reference pixel, which receives little (e.g., no) light, may provide a measurement of a dark current (i.e., leakage current). This dark current may be combined (e.g., subtracted) from the response of an active pixel to reduce (e.g., remove) this source of noise from the active pixel.

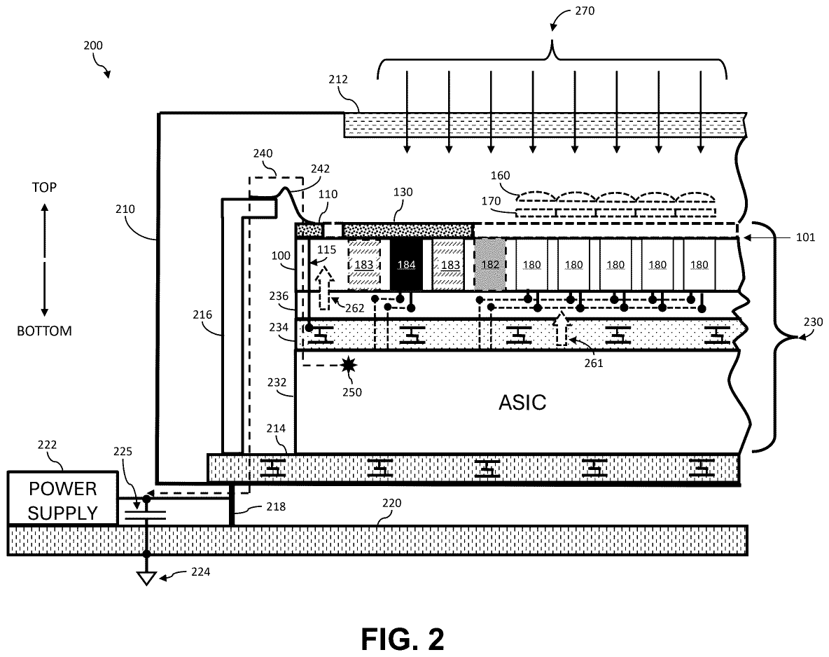

The active pixels in the active pixel region 140 receive light through an aperture in the shield 130. The light may also pass through a color filter 170 (e.g., Bayer filter) (see FIG. 2) and a microlens 160 (see FIG. 2) before reaching the two-dimensional array of pixels within the active pixel region 140. The active pixel region 140 may have an area that is less than the area defined by the aperture. As a result, a buffer region 131 may be defined between the active pixel region 140 and the inner edge of the shield 130.

The buffer region 131 may include buffer pixels to protect the pixels at the edges of the active pixel region from having a non-uniform electrical or optical environment. In other words, without the buffer pixels, the active pixels at the edges of the active pixel region 140 would not be surrounded by other pixels, which could affect their pixel signals. The buffer region can protect the pixels by providing spatial separation from the region at the edge of the shield.

The buffer region 131 may be surrounded (e.g., at an outer edge) by blocking pixels to block light (e.g., stray light) from leaking into the reference pixel region and/or to block stray charge (e.g. electrons) from flowing laterally through the thickness (i.e. bulk) of the sensor-die 100 into the reference pixel region. For example, the blocking pixels can be under the shield 130, inset from an edge of the shield. The blocking pixels may not be photosensitive but instead may include metallization (e.g., added metallization) to block this stray light and charge. For example, the blocking pixels may be configured to block light received at the buffer region 131 from reaching the reference pixels in the reference pixel region of the sensor-die 100.

The sensor-die 100 may be electrically and mechanically coupled to a semiconductor package (i.e., package). The package can be configured to contain and protect an image-sensor stack including the sensor-die 100 and can provide a means for connecting an external device (e.g., printed circuit board (PCB)) to circuitry (e.g., switching circuitry) of the image sensor.

FIG. 2 is a side cross-sectional view of a portion of a camera module according to a possible implementation of the present disclosure. The camera module 200 can include a printed circuit board (PCB 220) that includes a power supply 222. The power supply 222 can be configured to generate at least one power signal used to activate the electronics of the camera module 200. The power signal can be a direct current (DC) signal (i.e., voltage (V_{DD})). At least one decoupling capacitor 225 (i.e., bypass capacitor) can be used to reduce or eliminate noise (i.e., alternating current (AC) signals), which are combined with the power signal. As shown, a decoupling capacitor 225 can be included on the PCB 220 and coupled between an output of the power supply 222 and a ground plane (i.e., ground 224) of the PCB 220. The features shown in FIG. 2 are for illustrative purposes and not intended to limit the present disclosure. For example, the camera module 200 may include multiple power supplies and multiple decoupling capacitors, with at least one decoupling capacitor for each power supply connection.

As shown in FIG. 2, the camera module 200 includes an image sensor 210 coupled to the PCB 220. The image sensor 210 can include a substrate 214 configured to provide electrical connection, heat dissipation, and mechanical support to an image-sensor stack 230. In a possible implementation, the substrate 214 is a multilayer circuit board that includes traces and/or vias to electrically couple the circuitry of the image-sensor stack 230 to interconnects (e.g., pins, solder bumps, etc.) of the image sensor 210. The interconnects (i.e., package leads) can be electrically and mechanically coupled (e.g., soldered) to traces/vias on the PCB 220.

In practice, the package of the image sensor 210 may include many interconnects for coupling power and data signals between an electrical environment of the PCB and an electrical environment of the image sensor 210. For the purposes of this discussion, FIG. 2 illustrates an interconnect 218 configured to couple the power signal into the package of the image sensor 210 after the noise (e.g., from the power supply) has been filtered by the decoupling capacitor 225. The (filtered) power signal may be coupled to a lead frame 216 by traces and vias on the substrate 214. The lead frame 216 may be configured to provide a connection point for a wire 242 connected (e.g., wire-bonded) between the lead frame 216 and a pad 110. The pad 110 may be coupled to a through-silicon via (i.e., TSV 115) (e.g., at a side) in order to couple the power signal to the circuitry of the image-sensor stack 230.

The image-sensor stack 230 includes a sensor-die 100. As discussed, the sensor-die 100 can include active pixels 180 configured to convert received light 270 into electrical signals (e.g., charge, voltage). The package may include an optically-transparent window 212 (e.g., glass window) configured to seal the package from the environment without blocking the light 270 from reaching the active pixels 180. In a possible implementation, the light 270 may be focused onto the active pixels 180 by a microlens 160 and filtered for color (e.g., red, green, blue) by a color filter 170.

The image-sensor stack 230 further includes a metal layer deposited on the top surface, which includes the shield 130 and the pad 110. As discussed, the shield can be configured to block the light 270 from reaching a reference pixel 184 (or reference pixels). The reference pixel (or reference pixels) may be further isolated from the light 270 by a blocking pixel 183 (or blocking pixels) configured to block stray light and stray charge from reaching the reference pixel 184 (or reference pixels). As shown in FIG. 2, a blocking pixel 183 (or blocking pixels) may be configured to block light received in a space (i.e., region) between the pad 110 and the shield 130 from reaching the reference pixel 184 in the reference pixel region under the shield 130. In this implementation, the blocking pixel 183 may be positioned along an outer edge of the shield 130. The image-sensor stack 230 may further include a buffer pixel 182 (or buffer pixels) configured to transition between an active pixel region configured (by the shield 130) to receive the light 270 and a reference pixel region configured (by the shield 130) to not receive the light 270.

Pixel signals from the active pixels 180 may be coupled to a sensor metal stack 236, which includes routing circuitry configured to interconnect and route the pixels signals according to their rows and columns. The sensor metal stack 236 may be coupled to an application-specific integrated-circuit (i.e., ASIC) metal stack. The ASIC metal stack 234 can be coupled between the sensor metal stack 236 and an integrated circuit (e.g., ASIC 232). The ASIC metal stack 234 is configured to connect and route the pixel signals and the power signals to an ASIC 232. The ASIC 232 may be configured to perform the image processing necessary to generate a digital image based on the pixel signals. The image processing may include generating switching signals (e.g., high-frequency switching signals) to perform a variety of functions including (but not limited to) switching and routing pixel signals and digitizing pixel signals.

The switching may result in an undesirable noise signal that can interfere with the operation of the image sensor. The noise signal can correspond to a switching signal that leaks into other circuitry from ASIC. The switching signal can be parasitically coupled (e.g., capacitive or inductive coupling) through a leakage path to a signal line carrying a pixel signal. The parasitically coupled switching signal may have a relatively large amplitude compared to a pixel signal. As a result, the parasitically coupled switching signal (i.e., the noise signal) can alter pixel signals so that a rendered digital image includes artifacts.

As shown in FIG. 2, a noise source 250 may be located within the ASIC (e.g., at a switching node in the circuitry of the ASIC 232). The noise source 250 may generate a noise signal that can be coupled along different leakage paths to interact with the pixel signals. For example, the noise source 250 may generate a noise signal that travels within the ASIC 232 and along a first leakage path 261 so that it interacts with a pixel signal or a power signal in sensor metal stack 236. The noise source 250 may also generate a noise signal that travels within the ASIC 232 and along a second leakage path 262 along the TSV 115 so that it interacts with a pixel signal or a power signal in the sensor-die 100.

The noise signal may propagate along a decoupling path 240 to the decoupling capacitor 225 where it can be filtered to ground (e.g., eliminated). A length of the decoupling path 240 may reduce the efficiency of this filtering. For example, electrical loading (e.g., resistance, capacitance, and/or inductance) associated with the decoupling path 240 may resist the propagation of the noise signal. The disclosed image sensor addresses this problem by placing a noise-decoupling device on the top surface 101 of the image-sensor stack 230. For example, a noise-decoupling device may be electrically and mechanically connected to the metal layer on the top surface of the sensor-die 100. A noise-decoupling device at this position can reduce, or eliminate, the noise signal generated within the image-sensor stack 230 more efficiently than a decoupling capacitor at the PCB or at the substrate 214.

A noise-decoupling device coupled to the top surface 101 of the sensor-die 100 may be implemented as a surface-mount device (i.e., SMD) with at least two terminals. In one possible implementation the SMD is a filter (e.g., high pass filter, low pass filter, band pass filter) configured to decouple the noise signal from a power signal or a pixel signal. For example, the filter may include one or more capacitors and inductors in a T-topology (i.e., T-filter or a Pi-topology (i.e., Pi-filter). In another possible implementation, the SMD is a capacitor includes a first terminal and a second terminal.

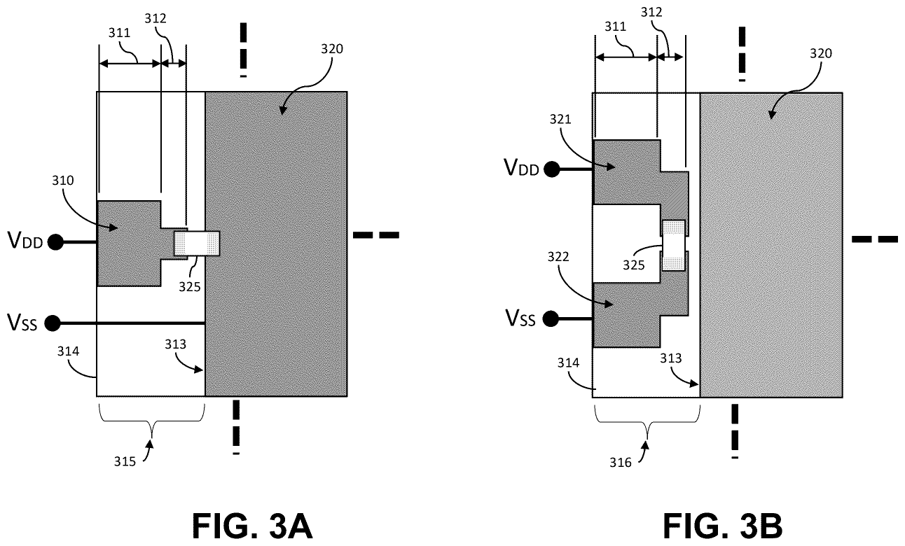

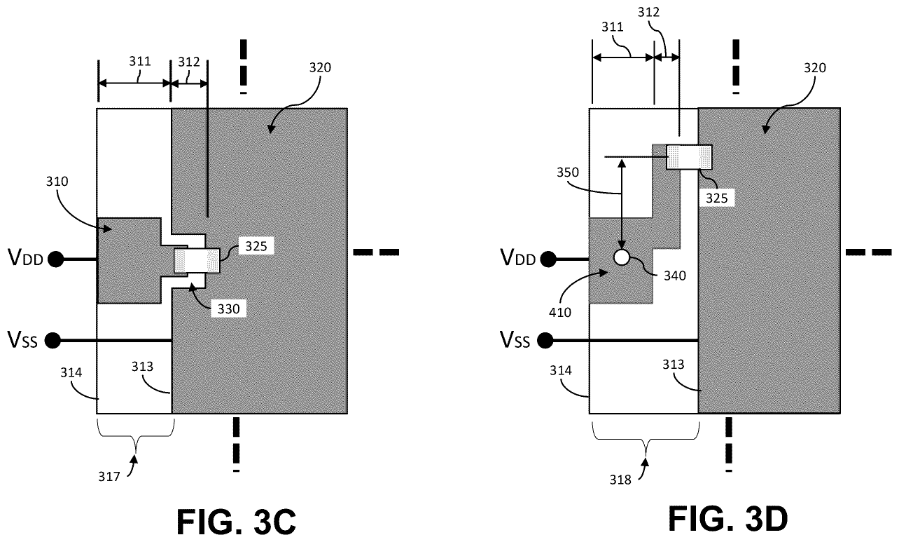

FIG. 3A is a top view of a portion of an image sensor according to a first possible implementation of the present disclosure. In particular, a pad 310 and a shield 320 of a metal layer on a top surface of a sensor die 314 is shown. The pad 310 includes an interconnect portion 311 and a decoupling portion 312.

The interconnect portion 311 can be configured to receive an interconnect that couples a power signal (e.g., upper rail voltage (V_{DD})) to the sensor die 314. In one possible implementation, the interconnect is a wire-bond coupled between the pad 310 and a lead frame of a package. In another possible implementation, the interconnect is a through-silicon via coupled between the pad 310 and a bump at a bottom surface of the image-sensor stack. The decoupling portion 312 can be configured to receive an electrical connection (e.g., solder connection) at a terminal of a noise-decoupling device (e.g., a surface-mount capacitor 325). Accordingly, the interconnect portion 311 and the decoupling portion 312 may have different areas and/or shapes. For example, the interconnect portion 311 can have a first area, and the decoupling portion 312 can have a second area that is smaller than the first area.

In a possible implementation, the interconnect portion 311 may be sized to reduce a difficulty in placing a wire bond. For example, the interconnect portion 311 may have an area that is greater than 1.5 times the area of a wire bond. Additionally, it may be necessary to place the wire bond before attaching the surface-mount capacitor 325 in order to provide clearance for a wire bond tool.

The shield 320 may be coupled to a ground (e.g., lower rail voltage (V_{SS}). The shield 320 may be configured to receive an electrical and mechanical connection (e.g., solder connection) at a terminal of the surface-mount capacitor 325. In other words, a first terminal of the surface-mount capacitor 325 may be coupled to the decoupling portion 312 while a second terminal of the surface-mount capacitor 325 may be coupled to the shield 320. In this configuration, the surface-mount capacitor 325 provides a decoupling path to ground that is at the top surface of the sensor die 314.

An outer edge 313 of the shield 320 and an outer edge of the sensor die 314 may define a pad region 315. The outer edge 313 of the shield 320 may be positioned to accommodate a length of the surface-mount capacitor 325. In other words, the pad region 315 may be based on the surface-mount capacitor 325. Blocking pixels (e.g., a linear array of blocking pixels) may be positioned under the outer edge 313 of the shield 320 to prevent light, received at the pad region 315, from reaching the reference pixels under the shield 320 (i.e., in the reference pixel region).

FIG. 3B is a top view of a portion of an image sensor according to a second possible implementation of the present disclosure. As shown, the metal layer on the top surface of the sensor die 314 can include a first pad 321 and a second pad 322. Each pad may include an interconnect portion 311 and a decoupling portion 312. The surface-mount capacitor 325 may be electrically and mechanically connected (e.g., soldered) at a first terminal to the decoupling portion 312 of the first pad 321 and may be further electrically and mechanically connected (e.g., soldered) at a second terminal to the decoupling portion 312 of the second pad 322.

The first pad 321 may be coupled to the power signal (e.g., upper rail voltage (V_{DD})) and the second pad 322 may be coupled to the ground (e.g., lower rail voltage (V_{SS})). This configuration may avoid a connection between the shield 320 and ground. Additionally, a pad region 316 in this second implementation (i.e., FIG. 3B) may be smaller than that pad region 315 of the first implementation (i.e., FIG. 3A) due to the orientation of the surface-mount capacitor 325. In other words, the outer edge 313 of the surface-mount capacitor 325 may be closer to the outer edge of the sensor die 314, which could eliminate the need for blocking pixels at the outer edge 313. Additionally, this configuration can allow the surface-mount capacitor 325 to be spatially offset from the wire bonds at the first pad 321 and the second pad 322, which may provide clearance for a wire-bonding tool, pick-and-place tool, and/or annealing tool.

FIG. 3C is a top view of a portion of an image sensor according to a third possible implementation of the present disclosure. As shown, the interconnect portion 311 of the pad is closest to (e.g., faces) an edge of the sensor die 314 and the decoupling portion 312 of the pad 310 is closest to (e.g., faces) an outer edge 313 of the shield 320. The outer edge 313 of the shield 320 is shaped so that the shield 320 surrounds a portion of the pad 310. As shown, the outer edge 313 may define a notch 330 configured to receive a portion (e.g., a majority) of the decoupling portion 312 of the pad 310. The notch 330 can enable a pad region 317 of the third implementation (i.e., FIG. 3C) to be smaller (e.g., narrower) than the pad region 315 of the first implementation (i.e., FIG. 3A).

FIG. 3D is a top view of a portion of an image sensor according to a fourth possible implementation of the present disclosure. As shown the decoupling portion 312 of a pad 410 may be shaped to provide an offset 350 between a through-silicon via 340 in the interconnect portion 311 and terminal of the surface-mount capacitor 325 in the decoupling portion 312. The decoupling portion 312 may include a terminal (e.g., solder terminal) positioned at the offset 350 to facilitate the connection of the surface-mount capacitor 325. The pad region 318 of the fourth implementation (i.e. FIG. 3D) may be larger (i.e. wider) than the pad region 317 of the third implementation (i.e., FIG. 3C). In the fourth implementation, there may or may not be a wire-bond in the interconnect portion 311. In this implementation, the interconnect portion 311 may be coupled to a through-silicon via 340. The TSV may communicate electrical signals (e.g., V_{DD}) through the sensor wafer to the top surface. FIGS. 3A-3D, which help describe features and configurations of the disclosure, are not intended to limit the scope of the disclosure to these particular arrangements. Variations to the features and configurations shown in these figures may be understood to be within the scope of the present disclosure. For example, other implementations may replace, or further include, a TSV drilled from the lowest side of the sensor to connect to the ASIC metal stack. The electrical issues and benefits of this disclosure equally apply to these implementations.

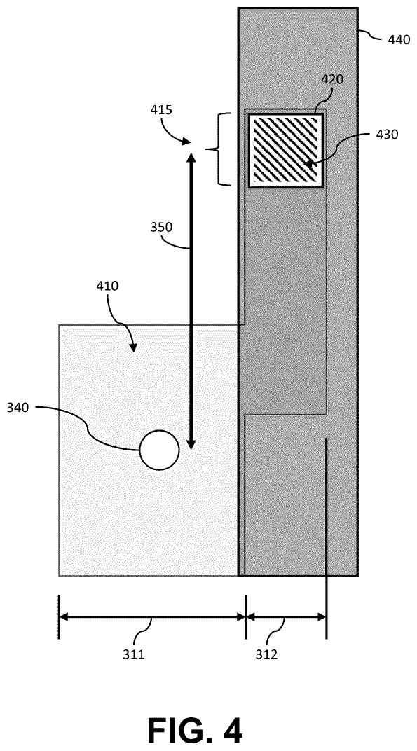

FIG. 4 is a top view of a pad of an image sensor according to a possible implementation of the present disclosure. The decoupling device may be coupled to the top surface in a variety of ways. FIG. 4 illustrates some features, which can facilitate the connection via solder. In FIG. 4, the pad 410 corresponds to the pad shown in FIG. 3D. As shown, the decoupling portion 312 includes a terminal 415 positioned at the offset 350 described previously. The terminal can include a solder layer 430 applied to the decoupling portion 312 of the pad 410. In a possible implementation, the solder layer 430 may include a solder mixture combined with a flux to facilitate a reflow during a soldering process. A solder mask 440 may be applied over, at least, a portion of the pad 410. The solder mask 440 may have an aperture 420 aligned with the solder layer 430 which can help to contain the solder during a soldering process. The aperture in the solder mask may also help to align the surface-mount capacitor 325 in a pick-and-place process, which can be used to position and place the surface-mount capacitor 325 before the soldering process.

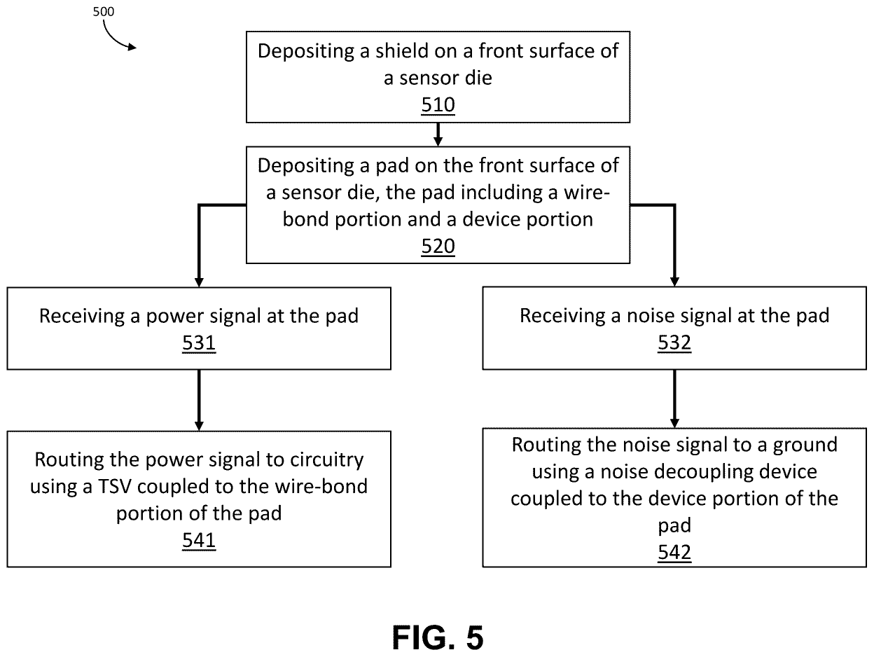

FIG. 5 is a flowchart of a method for reducing noise in an image sensor according to a possible implementation of the present disclosure. The method 500 includes depositing 510 a shield on a top surface of a sensor-die to block light from reaching reference pixels in a reference pixel region of the sensor-die and to pass light to active pixels in an active pixel region of the sensor-die. The method 500 further includes depositing 520 a pad on the top surface of the sensor-die. The pad includes a interconnect portion and a decoupling portion. The method 500 further includes receiving 531 a power signal at the pad. For example, the power signal may be a voltage from a power supply. The method 500 further includes receiving 532 a noise signal (i.e., noise) at the pad. For example, the noise signal may be a switching signal (e.g., voltage) from an integrated circuit. The method 500 further includes routing 541 the power signal to circuitry along a first path including a through-silicon via coupled to the interconnect portion of the pad. The method 500 further includes routing 542 the noise signal along a second path to a ground using a noise-decoupling device coupled to the decoupling portion of the pad. In a possible implementation, the noise-decoupling device is a capacitor, the ground is a shield, and the capacitor is soldered between the pad and the shield on the top surface of the sensor die within the package of the image sensor.

In the specification and/or figures, typical embodiments have been disclosed. The present disclosure is not limited to such exemplary embodiments. The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

1. An image sensor, comprising:
a sensor-die including active pixels and reference pixels;
a metal layer deposited on a top surface of the sensor-die, the metal layer including:
a shield configured to block light received at the top surface of the sensor-die from reaching the reference pixels and to pass the light to the active pixels; and
a pad including a interconnect portion and a decoupling portion; and
a noise-decoupling device coupled to the decoupling portion of the pad.

2. The image sensor according to claim 1, further comprising:
a wire that is bonded to the interconnect portion of the pad by a wire-bond.

3. The image sensor according to claim 1, wherein the noise-decoupling device is a surface-mount device electrically and mechanically coupled to the decoupling portion of the pad.

4. The image sensor according to claim 3, wherein the surface-mount device is a capacitor.

5. The image sensor according to claim 1, further comprising:
a through-silicon via coupled to the pad, the through-silicon via configured to electrically connect a power signal received at the pad to circuitry.

6. The image sensor according to claim 5, wherein:
the noise-decoupling device is coupled between the pad and a ground; and
the noise-decoupling device is configured to conduct a noise signal generated by the circuitry to the ground and not conduct the power signal to the ground.

7. The image sensor according to claim 1, further comprising:
a solder layer applied to the decoupling portion of the pad; and
a solder mask having an aperture aligned with the decoupling portion of the pad.

8. The image sensor according to claim 1, wherein the noise-decoupling device is connected at a first terminal to the decoupling portion of the pad and is connected at a second terminal to the shield.

9. The image sensor according to claim 8, wherein the shield is electrically connected to a ground.

10. The image sensor according to claim 1, wherein:
the metal layer includes a plurality of pads, each pad including a corresponding interconnect portion and a corresponding decoupling portion; and
the noise-decoupling device is soldered at a first terminal to a first decoupling portion of a first pad of the plurality of pads and is soldered at a second terminal to a second decoupling portion of a second pad of the plurality of pads.

11. The image sensor according to claim 1, wherein:
the shield defines a pad region on the top surface of the sensor-die between an outer edge of the shield and an edge of the sensor-die, wherein the pad is located in the pad region.

12. The image sensor according to claim 11, wherein the sensor-die includes:
a blocking pixel configured to block the light received at the pad region from reaching the reference pixels.

13. The image sensor according to claim 1, wherein:
the interconnect portion of the pad faces an edge of the sensor-die; and
the decoupling portion of the pad faces an outer edge of the shield.

14. The image sensor according to claim 13, wherein the outer edge of the shield is shaped so that the shield surrounds a portion of the pad.

15. The image sensor according to claim 13, wherein the interconnect portion has a first area and the decoupling portion has a second area, the second area being smaller than the first area.

16. The image sensor according to claim 1, wherein the image sensor is a backside illuminated sensor in a stacked configuration, the image sensor further including:
an application specific integrated circuit (ASIC) metal stack coupled between a sensor metal stack and an ASIC, the sensor metal stack coupled to a back surface of the sensor-die.

17. A method for reducing noise in an image sensor, the method comprising:
depositing a shield on a top surface of a sensor-die to block light from reaching reference pixels of the sensor-die and to pass the light to active pixels of the sensor-die;
depositing a pad on the top surface of the sensor-die, the pad including a interconnect portion and a decoupling portion;
receiving a power signal at the pad;
routing the power signal to circuitry using a through-silicon via coupled to the interconnect portion of the pad;
receiving a noise signal at the pad; and
routing the noise signal to a ground using a noise-decoupling device coupled to the decoupling portion of the pad.

18. The method for reducing the noise in the image sensor according to claim 17, wherein:
the noise-decoupling device is a capacitor;
the ground is the shield; and
the capacitor is electrically and mechanically coupled at a first terminal to the decoupling portion of the pad and electrically and mechanically coupled at a second terminal to the shield.

19. An image sensor including:
a printed circuit board including a power supply configured to generate a power signal;
a package coupled to the printed circuit board, the package including a lead frame configured to receive the power signal;
a sensor-die coupled to the lead frame to receive the power signal, the sensor-die including:
a shield deposited on a top surface of the sensor-die configured to block light from reaching reference pixels of the sensor-die and to pass the light to active pixels of the sensor-die; and
a pad deposited on the top surface of the sensor-die,
an integrated circuit including switching circuitry that generates a noise signal, the noise signal coupled to the pad by a through-silicon via; and
a noise-decoupling device coupled between the pad and a ground on the top surface of the sensor-die, the noise-decoupling device configured to conduct the noise signal at the pad to the ground and not conduct the power signal at the pad to the ground.

20. The image sensor according to claim 19, wherein the pad includes:
a interconnect portion coupled at a wire bond to a wire connecting the lead frame and the pad; and
a decoupling portion coupled at a solder connection to the noise-decoupling device.
